(19) United States
(12) Patent Application Publication
(10) Pub. No.: US 2006/0165904 A1
(43) Pub. Date: Jul. 27, 2006

(54) Semiconductor-manufacturing apparatus provided with ultraviolet light-emitting mechanism and method of treating semiconductor substrate using ultraviolet light emission

(75) Inventor: Naoki Ohara, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/040,863

(22) Filed: Jan. 21, 2005

(51) Int. Cl. B05D 3/02; G01J 3/10; C23C 16/00

(52) U.S. Cl. 427/372.2; 118/725; 250/504 R

(57) ABSTRACT

An apparatus for treating a semiconductor substrate includes a chamber an internal pressure of which can be controlled from a vacuum to the vicinity of an atmospheric pressure, multiple ultraviolet light emitters provided inside the chamber, a heater provided facing and parallel to the emitters inside the chamber, and a filter being disposed between the emitters and the heater and used for uniformizing the intensity of illumination of ultraviolet light; and further includes a configuration for uniformly distributing the intensity of illumination of ultraviolet light emitted from the emitters onto a surface of the heater.

### BACKGROUND OF THE INVENTION

The present invention relates to semiconductor thin film treatment technology used in manufacturing process of semiconductor circuit element formation; particularly to a semiconductor manufacturing apparatus and method of treating a semiconductor thin film using ultraviolet light emission.

Now that improving the properties of thin films is required as semiconductor chip sizes continue to shrink, there are various methods for improving thin films formed on semiconductor substrates.

One of such methods is to improve the properties of thin films formed on semiconductor substrates by treating the films using ultraviolet light emission. In U.S. Pat. No. 6,756,085, improving elastic modulus and material hardness using ultraviolet light emission is mentioned. In U.S. Pat. No. 6,756,085, change in dielectric constants of thin films by ±20% by ultraviolet light emission is also suggested. This change in dielectric constants by ±20%, however, is interpreted that the dielectric constants simply happened to be scattered within that range, not because the dielectric constants were controlled.

In this patent, there is no recognition of controlling dielectric constants by ultraviolet light emission; in fact, it is described that: “The UV curing process improves the mechanical properties of the low-k dielectric material, increasing material hardness while maintaining the dielectric pore, structure, density, and electrical properties” (Column 7, lines 37-41). In this patent, decrease in dielectric constants is achieved solely by annealing, etc. after UV treatment is conducted, and whether dielectric constants can be controlled by ultraviolet light emission is not suggested.

Additionally, as apparatuses having an ultraviolet light-emitting mechanism and methods of treating semiconductor substrates using ultraviolet light emission, for example, in U.S. Pat. No. 6,284,050, a configuration for ultraviolet light emission by installing a UV lamp and a heater being disposed below the central axis of the UV lamp is disclosed.

However, because a main configuration of this apparatus is the UV lamp being installed on the central axis of the apparatus for emitting ultraviolet light to thin films, ultraviolet light is disproportionately emitted toward the center. Therefore, only localized or standardized treatment effects can be expected because uniform UV emission to the entire thin film, adjustment of UV emission accommodating film properties, etc. are not taken into consideration.

Additionally, in this patent, although improved film hardness and adhesion by ultraviolet light emission are mentioned, no descriptions or suggestions of controlling dielectric constants are included.

### SUMMARY OF THE INVENTION

According to at least one embodiment of the present invention, one or more objects and effects described below can be achieved. Additionally, there is no need that all objects and effects are achieved in one embodiment, and it is acceptable that alternate objects and effects that are not described here (which can be comprehended or can be fundamental objects and effects from the descriptions of this specification) are achieved.

1) Dielectric constant values of thin films are lowered.

2) A degree of dielectric constant values of thin films to be lowered is accurately controlled.

3) A level of hydrophilic groups existing in the thin film is decreased.

4) Ultraviolet light is emitted onto substrates with uniform illumination.

5) A temperature of a substrate being exposed to ultraviolet light emission is to be kept at the same level during the ultraviolet light emission.

6) A uniform gas atmosphere is provided during the ultraviolet light emission.

According to one embodiment, the present invention provides an apparatus for treating a substrate comprises:
a chamber an internal pressure of which can be controlled from a vacuum to the vicinity of an atmospheric pressure;
multiple ultraviolet light emitters provided inside the chamber;
a heater provided facing and parallel to the emitters inside the chamber;
a filter being disposed between the emitters and the heater and used for uniformizing the illumination of ultraviolet light; and
at least any one of the following for uniformly distributing the intensity of ultraviolet light emitted from said emitters onto a surface of said heater:
(A) a configuration wherein said emitters composed of inside emitters disposed within a plane parallel to the heater surface and outside emitters arranged on an outer side of said inside emitters and disposed closer to the heater surface than said inside emitters;
(B) a configuration which further comprises reflectors for emitting reflected light as well as direct light of said emitters onto the substrate, and an angle-adjusting mechanism for enabling to vary reflection angles of said reflectors, or
(C) a configuration which further comprises a distance-adjusting mechanism for enabling to change a distance set for ultraviolet light emission between said filter and said heater.

The above-mentioned embodiment further can include the following embodiments:

The apparatus, wherein multiple gas inlet ports for introducing gas into the chamber in a direction from an inner circumferential surface to the center of the chamber are disposed;

The apparatus, further comprising a rotating mechanism for rotating the heater on its axis;

The apparatus, wherein the filter has a convex shape that a thickness in the vicinity of its center is thicker than a thickness in the vicinity of its outer perimeter, and the convex portion is processed to provide a curved surface;

The apparatus, wherein the emitters comprise inside emitters disposed within a flat surface parallel to the heater surface, and outside emitters disposed on an outer side of the inside emitters by bringing them closer to the heater surface than the inside emitters;

The apparatus, wherein the chamber comprises an upper chamber for housing the ultraviolet light emitters, a lower chamber surrounding the heater, and a flange installed between the upper chamber and the lower chamber;

The apparatus, wherein the filter is supported between the flange and the upper chamber;

The apparatus, wherein, in the flange, multiple gas inlet ports for introducing gas into the flange in a direction from an inner circumferential surface to the center of the chamber are disposed;

The apparatus, wherein the multiple gas inlet ports are disposed on an inner circumferential surface of the flange at even intervals;

The apparatus, further comprising a control unit installed on top of the chamber for controlling light emission by the ultraviolet light emitters;

The apparatus which comprises all configurations A, B, and C.

Additionally, according to another embodiment, the present invention provides an apparatus for treating semiconductor substrates comprising:
a chamber an internal pressure of which can be controlled from a vacuum to the vicinity of an atmospheric pressure;
multiple ultraviolet light emitters provided inside the chamber;
a heater provided facing and parallel to the emitters inside the chamber;
a filter being disposed between the emitters and the heater and used for uniformizing the illumination of ultraviolet light; and
multiple gas inlet ports for introducing gas into the chamber in a direction from an inner circumferential surface to the center of the chamber.

In the above, each element in one embodiment is mutually interchangeable with each element in another or more embodiments; each element can be combined. The present invention is not limited to the above-mentioned embodiments, but includes other embodiments which can achieve one or more objects mentioned above or objects other than those mentioned above.

Additionally, the present invention can be applied to methods for manufacturing low-k thin films; according to one embodiment, the present invention provides a method for treating semiconductor substrates comprising the steps of:
forming a low-k thin film on a substrate;
lowering a dielectric constant of the thin film formed by starting ultraviolet light emission to the thin film under a given set of conditions; and
continuing ultraviolet light emission under the given set of conditions and stopping the ultraviolet light emission at or near a lowest point where a dielectric constant value of the thin film becomes lowest and thereafter begins rising.

The above-mentioned embodiment can further include the following embodiments:

The method, wherein the ultraviolet light has an intensity of illumination of 1-50 mW/cm²;

The method, wherein ultraviolet light emission continues for less than 100 sec;

The method, which further comprises a step of establishing an N₂ or inert gas atmosphere before the ultraviolet light emission is started;

The method, wherein CO₂ is further added;

The method, wherein the low-k thin film is a film containing methyl groups;

The method, wherein the low-k thin film is a low-k C-doped silicon oxide film or silicon carbide film.

Additionally, according to another embodiment, the present invention provides a method for treating semiconductor substrates comprising the steps of:
forming a low-k thin film on a substrate;
lowering a dielectric constant of the thin film formed by starting ultraviolet light emission to the thin film under a given set of conditions; and
continuing ultraviolet light emission under the given set of conditions and stopping the ultraviolet light emission before the thin film is oxidized to an oxide film.

Furthermore, according to still another embodiment, the present invention provides a method for treating semiconductor substrates comprising the steps of:
forming a thin film having a first dielectric constant on a substrate;
determining emission time required for the dielectric constant value of the thin film to return to the first dielectric constant after the dielectric constant value of the thin film drops and then rises when ultraviolet light is emitted onto the thin film under a given set of conditions; and
emitting ultraviolet light onto a thin film under the given set of conditions for 10-50% of the emission time.

In the above, each element in one embodiment is mutually interchangeable with each element in another or more embodiments; each element can be combined. The present invention is not limited to the above-mentioned embodiments, but includes other embodiments which can achieve one or more objects mentioned above or objects other than those mentioned above.

### BRIEF DESCRIPTION OF THE DRAWINGS

The present invention is further described with reference to drawings attached, but the present invention is not limited to these drawings.

FIG. 1 is a schematic view showing an apparatus for treating semiconductor substrates according to one embodiment of the present invention. The figure is excessively simplified for the purpose of illustration.

FIG. 2 is an exploded perspective view of the apparatus shown in FIG. 1.

FIG. 3A is a schematic view showing one example of appropriate disposition of ultraviolet light emitters. FIG. 3B is a schematic view showing one example of flat-surface equidistant disposition of ultraviolet light emitters.

FIG. 4 is a schematic view showing one example of angle-adjusting mechanism for the reflectors.

FIG. 5A is a schematic lateral view showing one example of the filter. FIG. 5B is a schematic lateral view showing another example of the filter. FIG. 5C is a plan view of the respective filters.

FIG. 6 is a graph showing the intensity of illumination of ultraviolet light on the upper surface of the heater inside the chamber when six ultraviolet light emitters are used. The intensity of illumination of each ultraviolet light emitter and the total intensity of illumination of the ultraviolet light emitters are shown.

FIG. 7 is a schematic view showing one embodiment in which a rotating mechanism is installed in the heater.

FIG. 8 is a schematic view showing one embodiment of a gas-introducing flange.

FIG. 9 is a graph showing differences in illumination distribution uniformity according to different dispositions of ultraviolet light emitters.

FIG. 10 is a graph showing differences in illumination distribution uniformity according to different distances between ultraviolet light emitters and a workpiece.

FIG. 11 is FT-IR data showing one example of hydrophilic group effects in CO₂ atmosphere by ultraviolet light emission to a thin film.

FIG. 12 is a graph showing one example of the relation between dielectric constant values and UV emission time.

FIG. 13 is FT-IR data showing one example of film property change caused by excessive UV emission.

FIG. 14 is FT-IR data showing another example of film property change caused by excessive UV emission.

FIG. 15 is FT-IR data showing the state of CH₃ groups in the film before and after UV emission.

FIG. 16 is FT-IR data showing the state of Si—CH₃ groups in the film before and after UV emission.

### DETAILED DESCRIPTION OF THE PREFERRED EMBODIMENT

As described in the above, the apparatus for treating semiconductor substrates according to one embodiment of the present invention comprises (1) a chamber, an internal pressure of which can be controlled from a vacuum to the vicinity of an atmospheric pressure, (2) ultraviolet light emitters provided inside the chamber, (3) a heater provided facing and parallel to the emitters, (4) a filter being disposed between the emitters and the heater and used for uniformizing the illumination of ultraviolet light, and (5) a distance-adjusting mechanism for enabling to change a distance to be set between the filter and the heater.

In a different embodiment, in the above-mentioned apparatus, ultraviolet light can be emitted onto the entire thin film uniformly by controlling the illumination of ultraviolet light by altering a shape and a thickness of the filter.

Additionally, according to another embodiment, ultraviolet light emitted from the ultraviolet light emitters comprises direct light and reflected light, and uniformity of the illumination can be improved by disposing respective ultraviolet light emitters and reflectors appropriately.

Additionally, according to still another embodiment, uniformity of the illumination of the ultraviolet light provided by the emitters and reflectors can be adjusted by fine-tuning their dispositions and angles.

Furthermore, according to still another embodiment, disproportionate illumination of ultraviolet light in the vicinity of a thin film can be eliminated by rotating the heater.

Additionally, according to a different embodiment, distribution of illumination of ultraviolet light on a thin film can also be optimized by optimizing a distance between the ultraviolet light emitters and the heater. If a distance between the ultraviolet light emitters and the filter is not much, e.g., approximately 10-30 mm, the distance does not become a serious problem in terms of UV treatment because the light is diffuse light. In that case, optimizing a distance between the filter and the heater becomes valid.

Furthermore, according to a different embodiment, a heater temperature contributes to thin-film improvement by ultraviolet light emission; using a heater which can heat the entire thin film uniformly can improve distribution uniformity of the illumination.

Additionally, by introducing gas uniformly by symmetrically disposing gas inlet ports in a flange for introducing gas, disproportionate thin-film improvement can be eliminated:

Additionally, a cycle of ultraviolet light emission can be implemented by either of continuous emission or pulsed emission (including, e.g., 0-1000 kHz, 1 kHz, 10 kHz, 40 kHz, 100 kHz, 300 kHz, and values between the foregoing). Additionally, ultraviolet light emission can be implemented using a UV wavelength of about 100 nm to about 500 nm (preferably about 100 nm to about 400 nm), and at total emitter output of about 1 mW/cm² to about 1000 mW/cm² (including 2 mW/cm², 5 mW/cm², 10 mW/cm², 50 mW/cm², 100 mW/cm², 200 mW/cm², and values between the foregoing; preferably about 1 mW/cm² to about 50 mW/cm²). Additionally, the apparatus according to above-mentioned embodiment is not used for film formation, but for film-property modification treatment after a film is formed; hence energy required for film formation is unnecessary.

The present invention is further described with reference to drawings attached, but the present invention is not limited to these drawings.

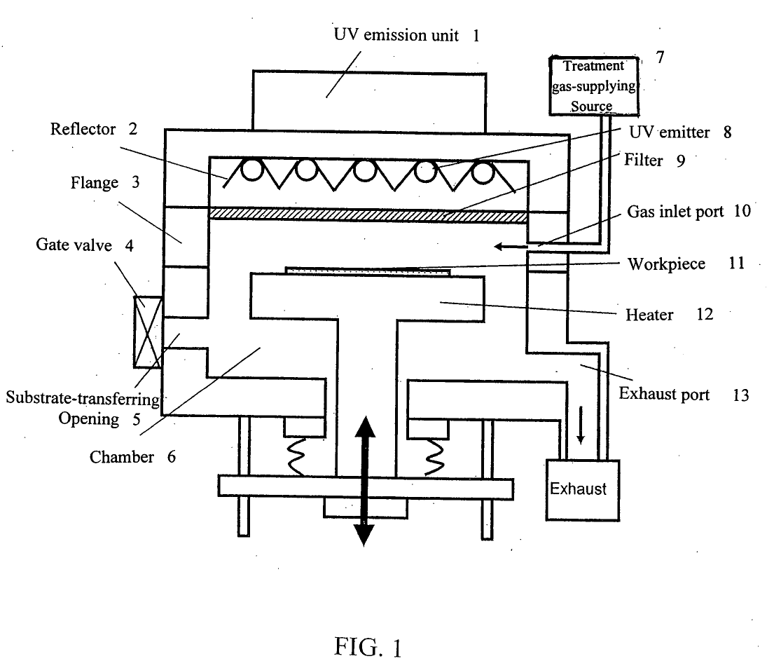

FIG. 1 is a schematic view showing an apparatus for treating semiconductor substrates according to one embodiment of the present invention. The figure is excessively simplified for the purpose of illustration. As shown in FIG. 1, the apparatus comprises a chamber 6, an internal pressure of which can be controlled from a vacuum to the vicinity of an atmospheric pressure, and a UV emission unit 1 installed on top of the chamber; further includes ultraviolet light emitters 8 for emitting ultraviolet light continuously or in a pulsed manner, a heater 12 provided facing and parallel to the emitters 8, and a filter 9 disposed facing and parallel to the ultraviolet light emitters 8 and the heater 12 between the two. In the UV emission unit 1, a control board for controlling transformer resistance, etc. and UV emission is housed; although placing the UV emission unit on top of the chamber is preferable in view of space efficiency, the unit can be provided separately from the chamber depending on an apparatus; it can be installed by the side of the chamber. The filter 9 is placed on top of a flange 3 through an O-ring (not shown). A workpiece 11, which is carried in/out to/from a substrate-transferring opening 5 via a gate valve 4, is placed on the heater 12. Gas is supplied into the chamber from a treatment gas-supplying source 7 through a gas inlet port 10 (The number of gas inlet ports provided can be one, but providing multiple gas inlet ports is preferable as described later.) Gas inside the chamber 6 is exhausted to the outside of the chamber through an exhaust port 13. Reflectors 2 are provided in the ultraviolet light emitters 8 so that direct light and reflected light reach the filter 9. Additionally, the reflectors 2, the heater 12 and the flange 3 are made of, e.g., aluminum respectively.

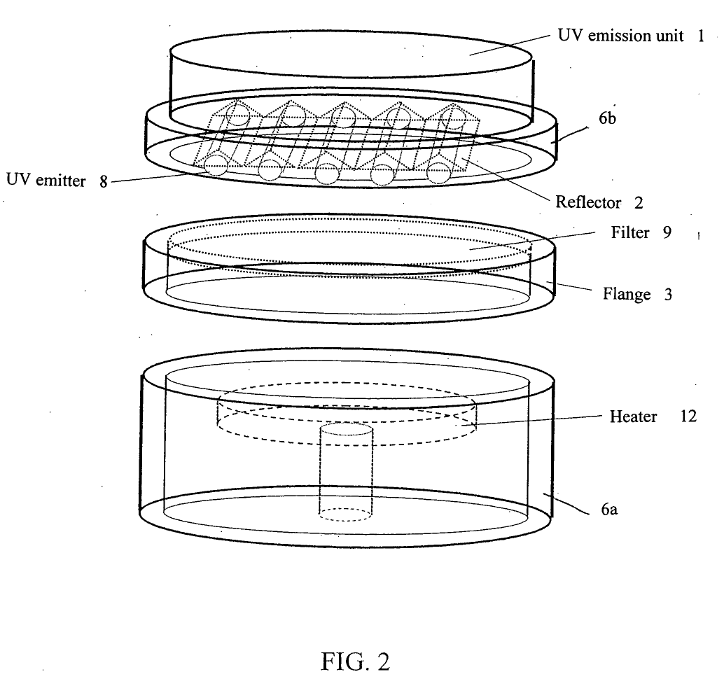

FIG. 2 is an exploded perspective view of the apparatus shown in FIG. 1. The chamber comprises an upper chamber 6b and a lower chamber 6a with the flange 3 being sandwiched between the two; the upper and lower chambers are disposed coaxially with the UV emission unit 1 and the heater 12. The ultraviolet light emitters 8 and the reflectors 2 are housed inside the upper chamber 6b. Additionally, the flange 3 on which the filter 9 is provided is separated from the lower chamber 6a (a substrate treatment portion), an internal pressure of which can be controlled from a vacuum to the vicinity of an atmospheric pressure, and the upper chamber 6b (a UV emission portion) possessing ultraviolet light emitters 8 for emitting the UV light continuously and in a pulsed manner. Additionally, the ultraviolet light emitters have an easily replaceable structure.

In this embodiment, the ultraviolet light emitters 8 provided inside the UV emission unit 1 are tubular and plural emitters are disposed parallel; the emitters 8 are disposed adequately for the purpose of uniformizing the illumination of ultraviolet light, and the dispositions are adjusted so as to be able to adjust the uniformity of the illumination; additionally, the reflectors 2 are provided so that ultraviolet light emitted from each ultraviolet light emitter is appropriately reflected, and angles of the reflectors 2 are adjustable so as to be able to uniformize the illumination. Although it is more advantageous if more emitters are provided, there is a limit to the number to be incorporated in the apparatus in view of space limitation. It is acceptable as long as multiple emitters are provided; normally 4-15 emitters; preferably 6-8 emitters. Additionally, a shape of the emitters is not particularly restricted, but is rodlike tubular or circular tube-shaped. A size and a length of each emitter can be the same or different.

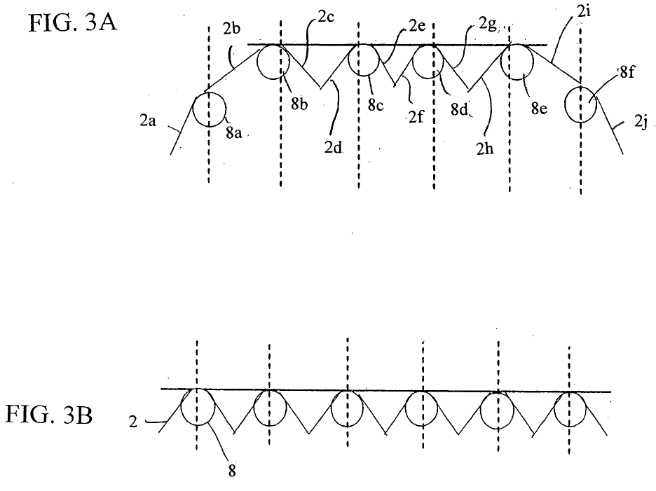

In the apparatus shown in FIG. 1, the emitters 8 are shown in a flat-surface equidistant disposition as shown in FIG. 3B. If the intensity of illumination of ultraviolet light in the vicinity of the outer circumference of a substrate becomes weakened, an appropriate disposition shown in FIG. 3A is valid. Additionally, although examples of six emitters are shown in both FIGS. 3A and 3B, the present invention is not limited to these examples. As compared with the equidistant flat-surface disposition shown in FIG. 3B, the uniformity of the illumination in the vicinity of the outer circumference of a substrate can be increased significantly in FIG. 3A. Furthermore, in FIG. 3A, for the emitters 8b, 8c, 8d, 8e which are disposed on the same flat surface, respective distances between outer emitters 8e, 8b and inner emitters 8d, 8c are widened and a distance between inner emitters 8d and 8c is narrowed; and the emitters 8a, 8f which are disposed on the outer side of the rest are moved toward the substrate. Furthermore, in FIG. 3A, angles of reflectors 2 are also changed; angles of outer reflectors 2a, 2b, 2i, 2j are adjusted so as to draw an arc. For reflectors 2c, 2d, 2e, 2f, 2g, 2h, their angles are adjusted according to respective distances between the emitters. Additionally, the reflectors 2a-2j can be made of a single member, but can also be made of multiple members having a stretchable structure.

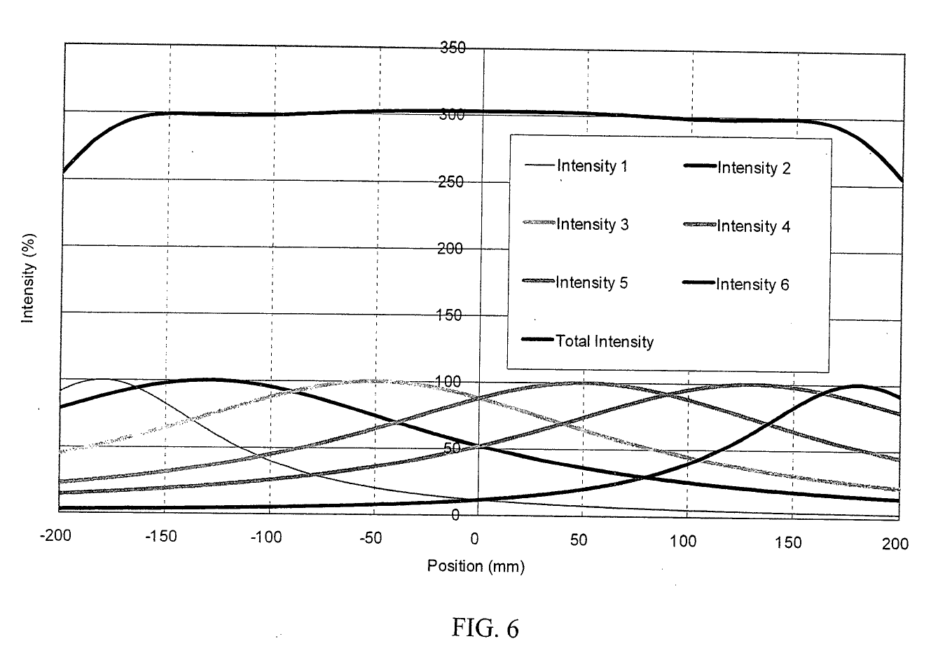

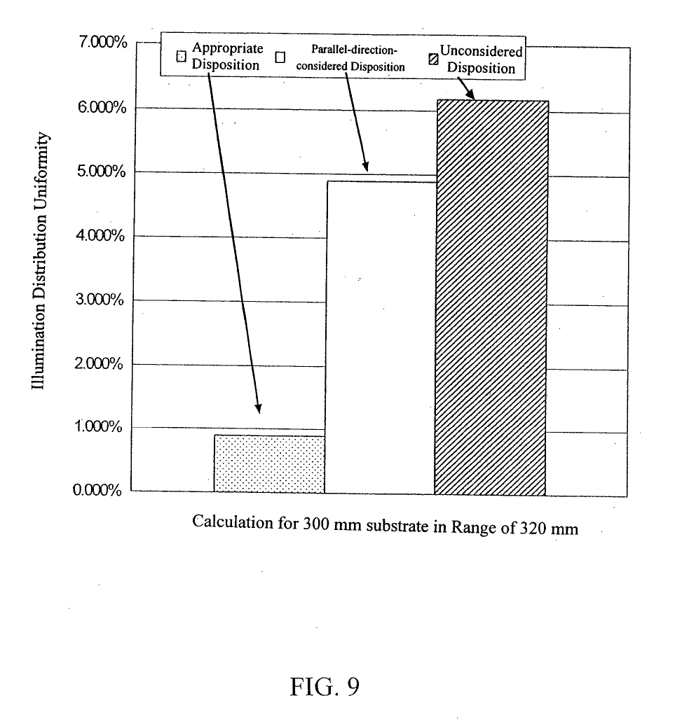

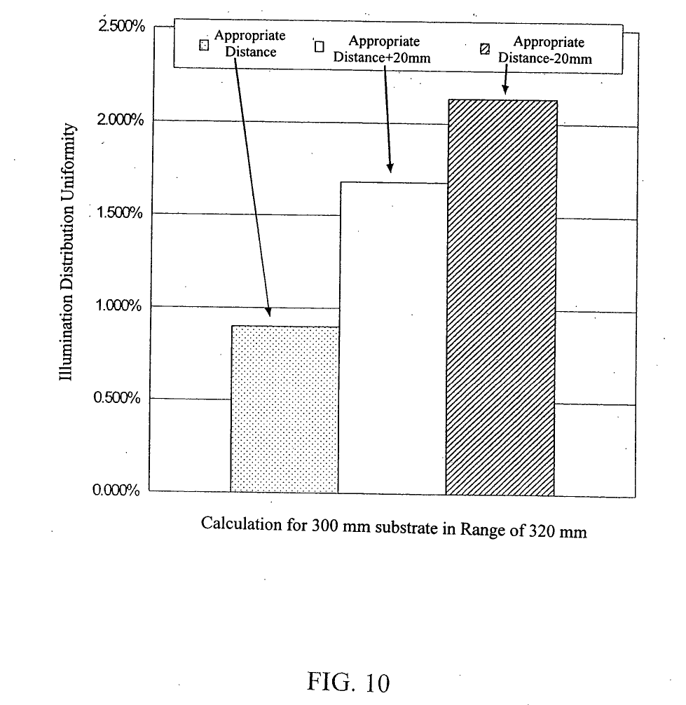

FIG. 9 is a graph showing differences in illumination distribution uniformity according to different dispositions of ultraviolet light emitters. (A filter is not taken into consideration.) In FIG. 9, “Appropriate Disposition” is obtained by calculating the distribution uniformity using the disposition (three-dimensional disposition) shown in FIG. 3A with six ultraviolet light emitters and the range of 320 nm (300 mm substrates are assumed). “Parallel-direction-considered Disposition” is a disposition that the above-mentioned Appropriate Disposition is modified in a two-dimensional direction (i.e., the positions of the emitters at both ends are not moved downward). “Unconsidered Disposition” is a disposition shown in FIG. 3B in which emitters are disposed at even intervals simply flatways. As is evident in FIG. 9, the uniformity of the illumination distribution by the emitters three-dimensionally disposed is significantly high, and nonuniformity is 1% and below. The uniformity of the illumination distribution by the emitters two-dimensionally disposed with their dispositions optimized in a parallel direction is better than the distribution uniformity in equidistant disposition, but is worse than the distribution uniformity by the emitters three-dimensionally disposed. Additionally, in FIG. 9, assuming point source of light, calculation was made using a method of overlapping the illumination of each point light source; by specifying a light-source range in consideration of an interval between light sources and a distance to a substrate as parameters, the illumination of each light source was overlapped within that range. The uniformity was calculated here by overlapping the illumination at 10 mm intervals. The same applies to FIGS. 6 and 10 described later.

Additionally, as described later, regarding the outer circumferential portion on the outer side of 320 mm, the illumination tends to drop; as a result, there is a possibility that nonuniformity of film properties in the vicinity of an edge portion of a workpiece may occur. For this reason, in one embodiment, such problem is solved using a filter shape as described later.

Additionally, although respective dispositions shown in FIGS. 3A and 3B can be fixed, preferably by providing a position-adjusting mechanism enabling to change the disposition shown in FIG. 3B to the disposition shown in FIG. 3A, etc. (not limited to the disposition shown in FIG. 3A), the uniformity of the illumination is adapted to be adjustable. For example, without fixing the emitters' positions completely and by make subtle positioning adjustment possible by providing play in a flat-surface direction, identifying the positions is ensured.

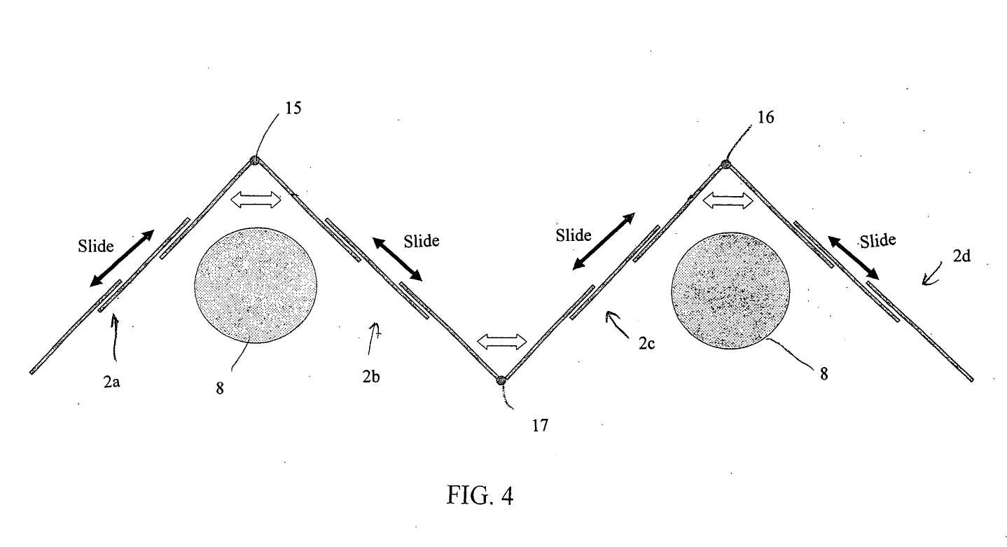

Additionally, a reflector angle is preferably adjustable. One example is shown in FIG. 4. In FIG. 4, reflectors 2a, 2b are openably/closably supported by a movable axis 15 respectively; reflectors 2b, 2c are openably/closably supported by a movable axis 17 respectively; reflectors 2c, 2c are openably/closably supported by a movable axis 16 respectively. The movable axes 15, 16 are movable laterally in the figure; the movable axis 17 is movable in either direction, laterally and up and down. Respective reflectors comprise multiple pieces of sliding plates being laid over one another; by changing positional relation among the movable axes 15, 16, and 17, angles of reflectors are changed, and at the same time, angle adjustment becomes possible by sliding plates being expanding and contracting. In order to identify an angle, a dial meter, etc. can be used.

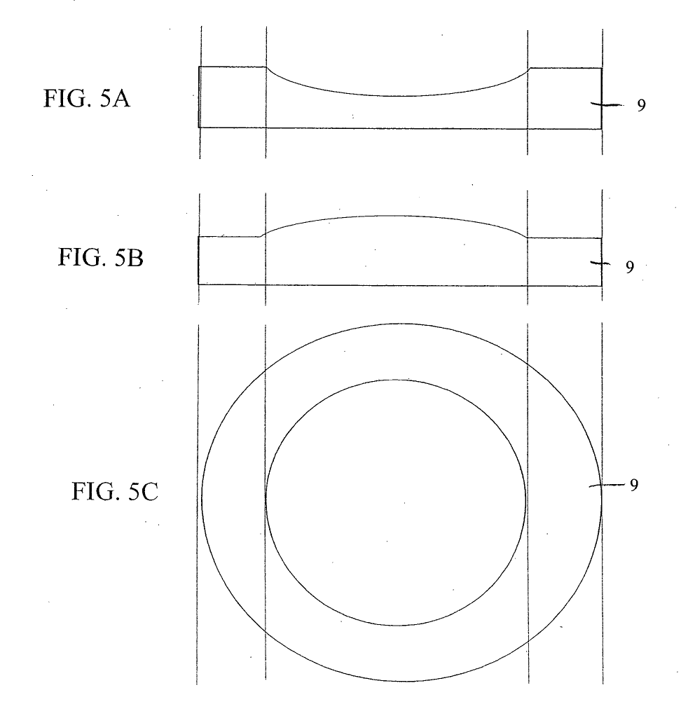

The filter 9 shown in FIG. 1 is planate, but in order to improve uniformity of the illumination, filters processed to provide a curved surface as shown in FIGS. 5A-5C can be used. FIG. 5A is a schematic lateral view showing one example of a filter (effective when the illumination in the vicinity of a heater edge is high, etc.). FIG. 5B is a schematic lateral view showing another example of a filter (effective when the illumination in the vicinity of the center is high, etc.). FIG. 5C is a plan view of those filters. If a distance between ultraviolet light emitters and a filter is, for example, about 10 mm to about 30 mm, which is relatively short, ultraviolet light reaches the filter uniformly because the light is diffuse. However, because a filter diameter cannot be configured to be very large structurally as compared with a diameter of a heater (or a workpiece), ultraviolet light consists of point sources superimposed even though multiple ultraviolet light emitters are provided. As a result, the illumination in the vicinity of inner walls of a chamber or in the vicinity of a heater edge inevitably tends to become weaker than the illumination in the vicinity of the center. Consequently, because the illumination of the light received by the vicinity of outer circumference of a workpiece becomes weak, property modification effects on the workpiece by ultraviolet light are apt to be uneven. For this reason, a distance between the filter and a workpiece (about 5 mm to about 60 mm in one embodiment; preferably about 10 mm to about 40 mm) is important for the uniformity, but there may be cases in which ensuring the uniformity only by the distance is difficult.

FIG. 6 is a graph showing the illumination of ultraviolet light on the upper surface (the emission surface) of the heater inside the chamber when six ultraviolet light emitters (positioned in the Appropriate Disposition shown in FIG. 3A) are used. (The filter is not taken into consideration.) The intensity of illumination of ultraviolet light emitted by each ultraviolet light emitter (Intensity 1-6) and the Total Intensity are shown. As seen from FIG. 6, even with the Appropriate Disposition shown in FIG. 3A being used, the intensity of illumination becomes weak in the vicinity of the heater edge (the vicinity of chamber inner walls). (Additionally, the uniformity within the range of 320 mm excluding the vicinity of the edge is uniform illumination of 1σ1% and below.) In one example in which the illumination was actually measured, the illumination in the vicinity of the edge is about 80% to about 90% of the illumination in the vicinity of the center. As one embodiment of improving such nonuniformity, adopting a filter shape for the case shown in FIG. 5B, in which the illumination in the vicinity of the center is high, can be mentioned. In other words, a thickness of a filter portion for which the illumination is low is reduced. A filter thickness can be estimated roughly by using the following formula:
I=IoExp[−4P*T*k/R] (I=Permeation Intensity, Io=Initial Intensity, P=pi, T=Thickness, k=Damping Factor, R=Wave Length)

Additionally, in one embodiment, a thickness of an edge portion of a filter is about 70% to about 95% of a thickness of the vicinity of the center (including 75%, 80%, 85%, 90%, and values between the foregoing; preferably 80-90%). Preferably, curved surface work shown in FIG. 5B (or spherical surface work) is provided.

Additionally, a filter can comprise quartz glass, etc. For example, SiCl₄ quartz glass (tetrachlorosilicon quartz glass) can be used. Because of the nature of ultraviolet light, it becomes more difficult for ultraviolet light to permeate through glass as its wavelength becomes shorter; and it becomes particularly difficult for a wavelength shorter than vacuum ultraviolet part to permeate through glass. However, SiCl₄ mentioned above has excellent permeability. Other than this, fluoride glasses such as CaF, which has excellent ultraviolet light permeation characteristics, can be used.

Additionally, if quartz glass is used, a filter thickness of 20 mm and above (25 mm, 30 mm, 40 mm, 50 mm and values between the foregoing included), which can endure atmospheric pressure in a vacuum, is necessary.

Additionally, this embodiment is adapted to have a configuration that the filter is placed and installed in a flange so as to facilitate filter maintenance and replacement.

For a heater, its temperature can be adjusted within the range of about 0° C. to about 650° C. in one embodiment. Additionally, a heater having excellent temperature distribution characteristics is preferably used. As a heater having excellent temperature distribution, a heater satisfying one and more required conditions described as follows can be preferably used: (1) excellent in temperature follow, (2) high heat capacity, (3) heater wiring inside the heater is buried deeply from a heater surface, (4) sensors such as TC gauges for reading a temperature are provided in multiple place instead of one place, and a temperature can be read, (5) by providing independent wiring corresponding to the one provided in a sensor area, accurate heating/temperature control for each substrate area can be made, and so forth.

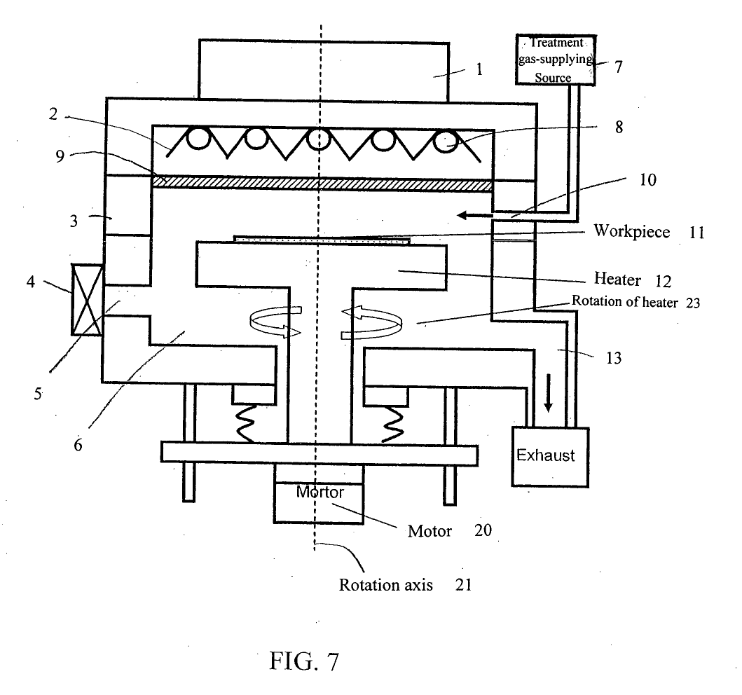

Additionally, a heater preferably possesses a rotating mechanism (about 0.1 rpm to about 100 rpm; preferably about 1 rpm to about 60 rpm). By rotating a workpiece during ultraviolet light treatment, uniformity of ultraviolet light emission can be increased. FIG. 7 is a schematic view showing one embodiment in which the rotating mechanism is installed in the heater. The same symbols are used for portions common to FIG. 1. In FIG. 7, a motor 20 is provided so that the heater 12 can be rotated; the heater 12 is rotated on a rotation axis 21 by the motor 20 as shown by arrow 23. Additionally, a rotation direction can be either of clockwise or counterclockwise rotation; additionally, a rotation direction can be changed during a single round of treatment process. Additionally, a rotation axis is not necessarily positioned at the center of the heater; by slightly moving the rotation axis away from the center of the heater (the center of a workpiece), it is also possible to increase the uniformity of ultraviolet light emission.

Furthermore, so as to be able to adjust the illumination and uniformity of ultraviolet light emitted onto a workpiece, a structure enabling a distance between the filter and the heater to be adjustable is preferably provided. For example, by making a heater position changeable by about 5 mm to about 60 mm, and by adjusting a heater position by specifying a distance via a motor using an encoder, a distance between the filter and the heater can be adjusted.

FIG. 10 is a graph showing differences in illumination distribution uniformity according to a distance between ultraviolet light emitters and a workpiece. (The filter is not taken into consideration.) “Appropriate Disposition” in FIG. 10 is based on the Appropriate Disposition shown in FIG. 3A; in this case, the Appropriate Disposition is calculated using 135 mm as a distance from center four emitters to a surface exposed to UV emission and 65 mm as a distance from emitters disposed on both edges to the surface exposed to UV emission (based on the lowest point of the emitters). Although nonuniformity of the illumination is 1% and below using the appropriate distance, nonuniformity exceeds 1.5% if the appropriate distance is increased by 20 mm, or nonuniformity exceeds 2% if the appropriate distance is decreased by 20 mm.

The gas inlet ports are described below. The gas inlet ports are used for introducing inert gas, etc. into the chamber during ultraviolet light emission. Any configuration, which can achieve this purpose, can be used. Preferably, the gas inlet ports are disposed so that the gas is introduced into the chamber uniformly. As one example, multiple gas inlet ports are provided; multiple gas inlet ports are disposed in an inner periphery of the chamber at even intervals so that gas is introduced into the chamber toward the center of the chamber. The number of gas inlet ports is preferably 3-20, more preferably 4-12.

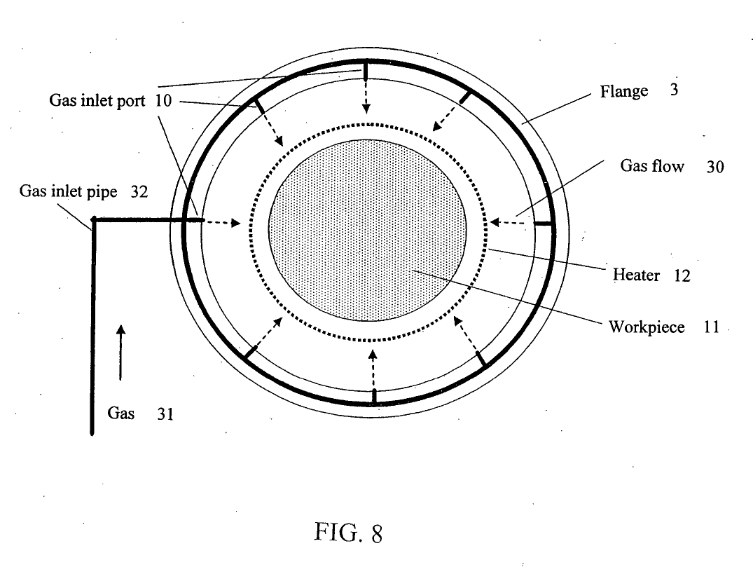

Additionally, the gas inlet ports can be provided inside the flange. One example of providing the gas inlet ports inside the flange is shown in FIG. 8. In FIG. 8, gas 31 is introduced toward a workpiece 11 placed on the heater 12 via a gas inlet pipe 32 and gas inlet ports 10 provided inside the flange. Multiple (eight) gas inlet ports 10 are provided and are disposed symmetrically (45-degree symmetrical disposition) so as to produce a uniform treatment atmosphere.

The method of emitting ultraviolet light is described below.

The present invention is not limited to this embodiment, but according to one embodiment, the method can be implemented by the treatment steps including: (1) forming a low-k thin film on a substrate, (2) starting ultraviolet light emission to the thin film under a given set of conditions to lower a dielectric constant of the thin film formed, and (3) continuing ultraviolet light emission under the given set of conditions and stopping the ultraviolet light emission when the thin film's dielectric constant gets to and near the lowest point and before it begins rising.

Although thin films to be treated by this method are not limited, low-k C-doped silicon oxide films or silicon carbide films formed on semiconductor substrates can be treated by this method. These silicon-containing low-k films can be formed using hydrocarbon-containing silicon compounds as precursors.

For example, thin films formed using source gases including at least one material expressed by chemical formulas 1-6 shown below can be mentioned. Additionally, materials disclosed in U.S. Pat. No. 6,455,445 can be used. The entire disclosure of this U.S. patent is incorporated hereby by reference. 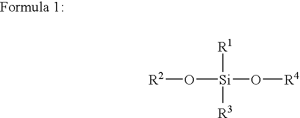
(In the above formula, R¹, R², R³ and R⁴ are any one of CH₃, C₂H₅, C₃H₇, C₆H₅.)

DMDMOS (dimethyldimethoxysilane), DEDEOS (diethyldiethoxyoxysilane), etc. can be mentioned as compounds expressed by Formula 1. 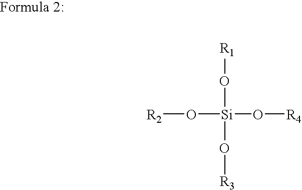
(In the above formula, R¹, R², R³ and R⁴ are any one of CH₃, C₂H₅, C₃H₇, C₆H₅.)

TMOS (tetramethoxysilane), etc. can be mentioned as compounds expressed by Formula 2. 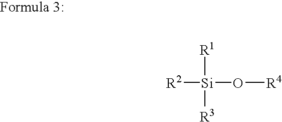
(In the above formula, R¹, R², R³ and R⁴ are any one of CH₃, C₂H₅, C₃H₇, C₆H₅.)

PTMOS (phenyltrimethoxysilane), etc. can be mentioned as compounds expressed by Formula 3.

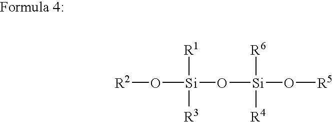

(In the above formula, R¹, R², R³, R⁴, R⁵ and R⁶ are any one of CH₃, C₂H₅, C₃H₅.)

DMOTMDS (1,3-dimethoxytetramethyldisiloxane) etc. can be mentioned as compounds expressed by Formula 4. 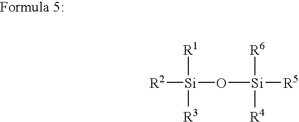
(In the above formula, R¹, R², , R R⁴, R⁵ and R⁶ are any one of CH₃, C₂H₅, C₃H₇, C₆H₅.)

HMDS (hexamethyldisilane), etc. can be mentioned as the compound expressed by Formula 5. 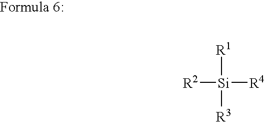
(In the above formula, R¹, R², R³ and R⁴ are any one of CH₃, C₂H₅, C₃H₇, C₆H₅.)

DVDMS (divinyldimethylsilane), 4MS (tetramethylsilane), etc. can be mentioned as compounds expressed by Formula 6. 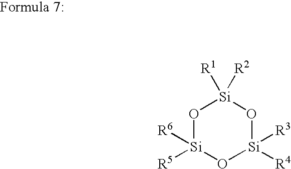
(In the above formula, R¹, R², R³, R⁴, R⁵ and R⁶ are any one of CH₃, C₂H₃, C₂H₅, C₃H₇, C₆H₅.)

OMCTS (octamethylcyclotrisiloxane), etc. can be mentioned as the compound expressed by Formula 7.

Additionally, if oxygen atoms are not included in materials as in Formula 6, oxygen atoms may be added separately as oxidized gas.

Ultraviolet light emission treatment can be implemented by carrying a substrate on which a thin film is formed into an ultraviolet light treatment apparatus. Additionally, by attaching an ultraviolet light treatment apparatus to a CVD apparatus for forming a thin film, film formation and ultraviolet light treatment can be implemented in a single apparatus; structurally however, it is preferable to separate an ultraviolet light treatment apparatus from a CVD apparatus.

According to one embodiment of ultraviolet light treatment, with pressures inside the chamber being set around atmospheric pressure of about 0.1 Torr using gas selected from Ar, CO, CO₂, C₂H₄, CH₄, H₂, He, Kr, Ne, N₂, N₂O, O₂, Xe, alcohol-containing CH gas and organic gas (a gas flow rate can be selected from about 0.1 sccm to about 20 slm in one embodiment, preferably about 500 sccm to about 1000 sccm), and by placing a workpiece on a heater whose temperature is set at about 0° C. to about 650° C., ultraviolet light at a wavelength of about 100 nm to about 400 nm, and an output of about 1 mW/cm² to about 1000 mW/cm², preferably about 1 mW/cm² to about 100 mW/cm², more preferably about 5 mW/cm² to about 50 mW/cm² can be emitted from ultraviolet light emitters disposed at an appropriate distance continuously or in a pulsed manner at frequencies of about 0 Hz to about 1000 Hz to a thin film formed on a semiconductor substrate with the heater being rotating on its center as shown in FIG. 7. (Treatment time can be set at about 5 sec. to about 300 sec., preferably about 20 sec. to about 200 sec., more preferably about 30 sec. to about 100 sec.) This semiconductor-manufacturing apparatus is able to perform a series of these steps (the treatment process) as an automatic sequence; the treatment process comprises the steps of introducing gas, emitting ultraviolet light, stopping the UV emission and stopping supplying the gas.

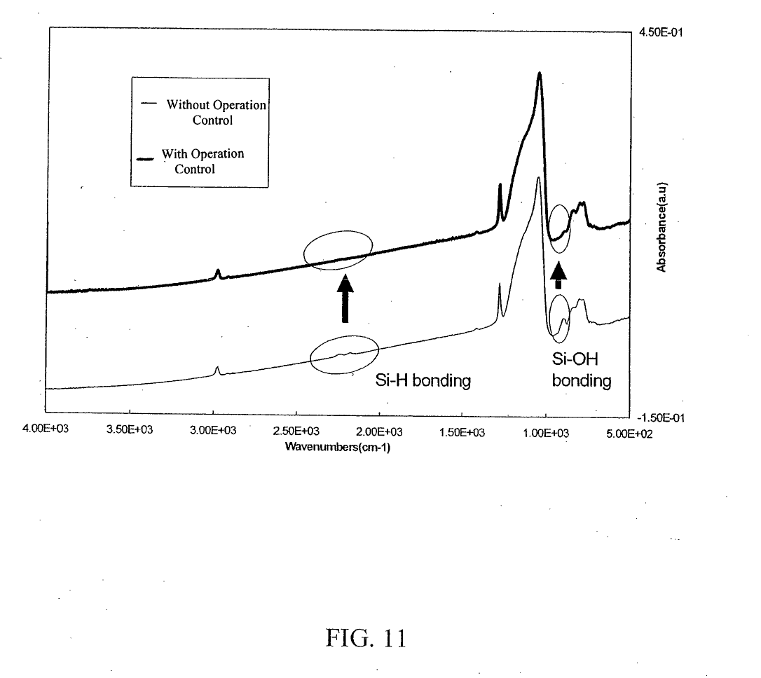

Additionally, as a gas to be introduced, it is preferable to use N₂ or inert gases which are not dissociated by ultraviolet light inside the chamber; using such a gas can lower a dielectric constant effectively. However, according to circumstances, N₂ or inert gases which are not dissociated by ultraviolet light may generate hydrophilic groups (Si—H groups, Si—H groups). Although hydrophilic groups existing in the thin film may have possibilities to deteriorate thin film characteristics, by suppressing their peaks, deteriorations of thin film characteristics can be prevented. Suppressing generation of hydrophilic groups becomes possible by introducing CO₂ (500 sccm and below in one embodiment) into the chamber (See FIG. 11, Embodiment 10). This is thought to be caused by CO₂ being decomposed by ultraviolet light and reacting with molecules comprising the thin film. By adding CO₂, strengthening the thin film also becomes possible; however, because CO₂ is dissociated by ultraviolet light, the thin film is oxidized, and its dielectric constant tends to rise slightly.

When ultraviolet light is emitted to a thin film formed on a semiconductor substrate by the ultraviolet light treatment apparatus, a dielectric constant of the thin film can be lowered. Regarding this phenomenon, various contributing factors including the following phenomenon can be thought:

When ultraviolet light is emitted onto bonds between permanent dipoles in the thin film (e.g., bonding of two atoms, molecules having different polarity such as bonding of C—O (carbon-oxygen), Si—CH₃ (silicon-methyl groups)), bonding between permanent dipoles is broken (in this case, because of Van der Waals forces, intermolecular bonding can be easily cur off by ultraviolet light); because the bonding disappeared, permanent dipoles themselves become unstable; hence repulsion caused by electrostatic force occurs between permanent dipoles; by this force, polarity reversal occurs. When ultraviolet light emission is stopped, bonds working on between permanent dipoles are formed again because permanent dipoles whose polarity orientation was reversed try to stabilize themselves in that state. By this, the polarity of the thin film itself is lowered because of polarity reversal; as a result, its dielectric constant is lowered.

However, when ultraviolet light is emitted onto the thin film, an electric field is formed in the thin film and electric charges are generated on a substrate surface; because of this, if UV emission time is lengthened, more electric charges are generated, and by their electrostatic force, permanent dipoles in the polarity-reversed thin film are aligned in a direction of the electric field by orientational polarization and polarity shows a tendency of increasing. As a result, a dielectric constant shows a tendency of increasing.

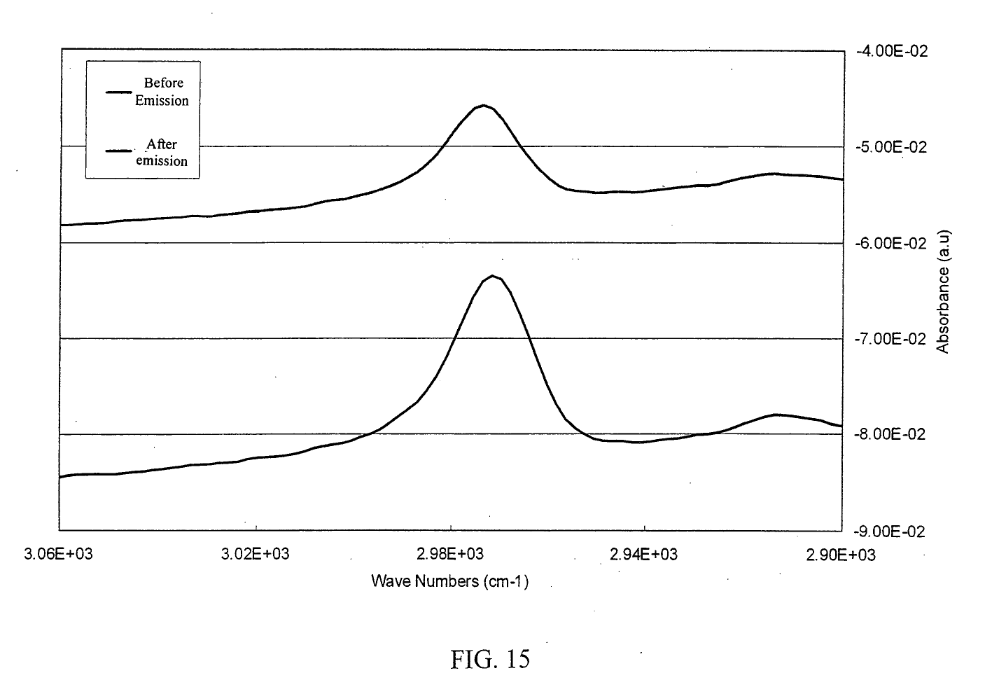

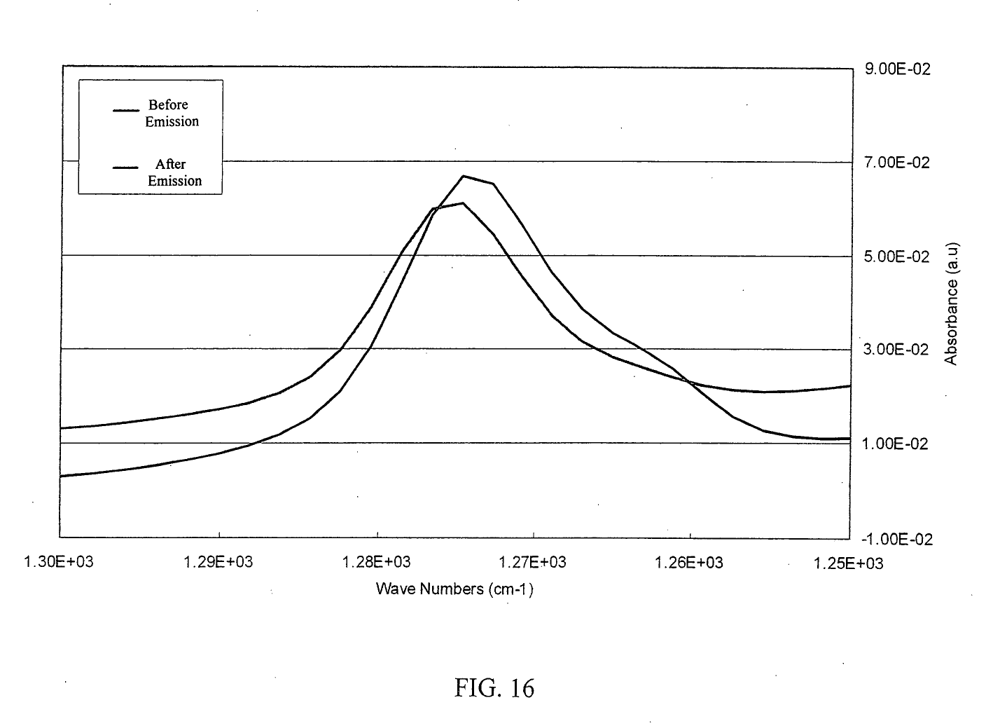

Additionally, when ultraviolet light is emitted onto the thin film, methyl groups in the thin film are decreased (See FIG. 15, Embodiment 3.); hence with methyl groups having high polarizability being decreased, a dielectric constant is lowered. (A level of Si—CH₃ groups is also decreased (See FIG. 16, Embodiment 3.)

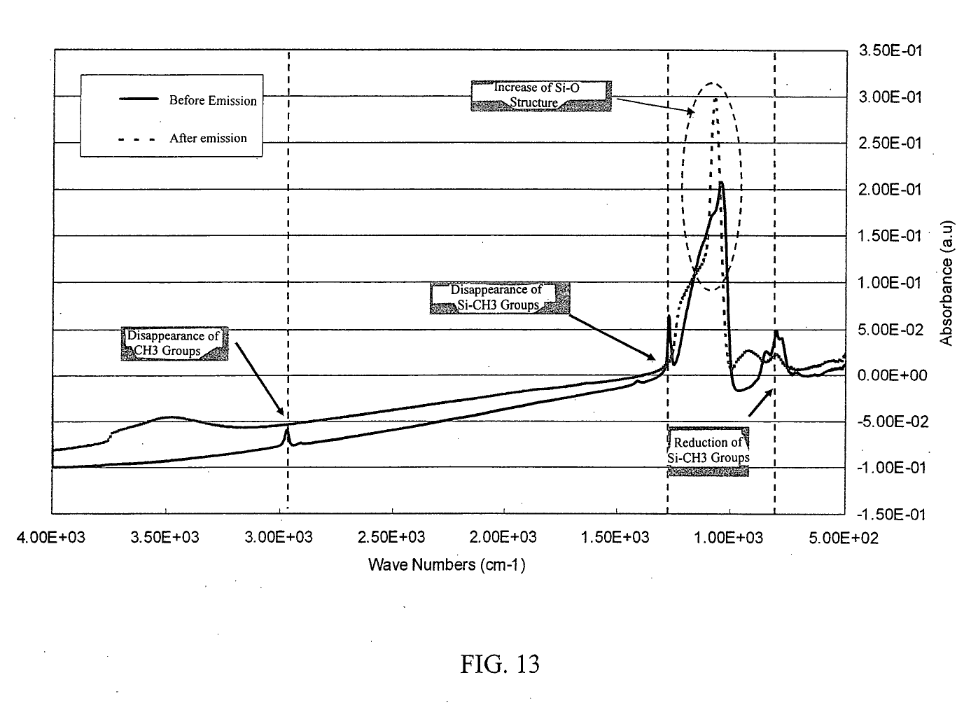

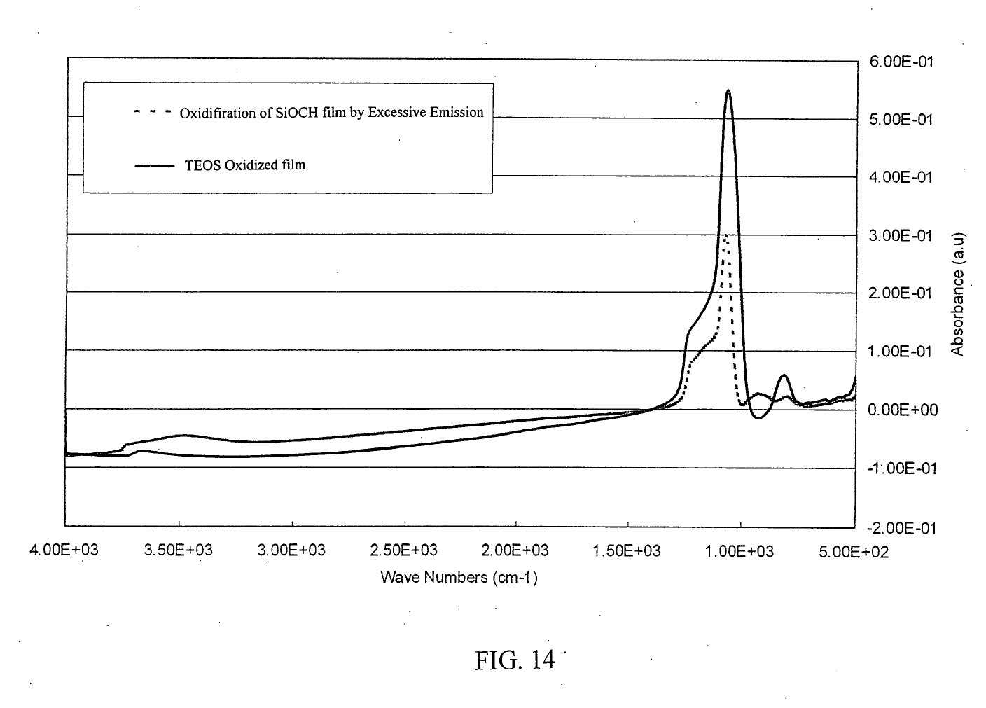

However, if the UV emission time is lengthened similarly to the above-mentioned, methyl groups disappear (See FIG. 13, Comparative Example 1) and the thin film becomes an oxidized film (See FIG. 14, Comparative Example 2); as a result, a dielectric constant shows a tendency of increasing. Generally, because SiOCH-containing low-k films retain low dielectric constants by having a certain level of methyl groups, a dielectric constant rises if the methyl groups are suddenly lost, film composition changes to SiO films', and its dielectric constant rises. A dielectric constant can be lowered if a level of methyl groups contained in the film is adjusted by ultraviolet light emission.

The above-mentioned contributing factor for lowering dielectric constants can be thought; if the UV emission time is lengthened, dielectric constants are shifted to increase. As a result, because of the above-mentioned contributing factors, optimized UV emission time is required in order to lower dielectric constants. Additionally, the present invention is not limited to the above-mentioned theory. Furthermore, in order to control dielectric constants, N₂ or inert gases with which an atmospheric gas inside the chamber is not dissociated by ultraviolet light may be used.

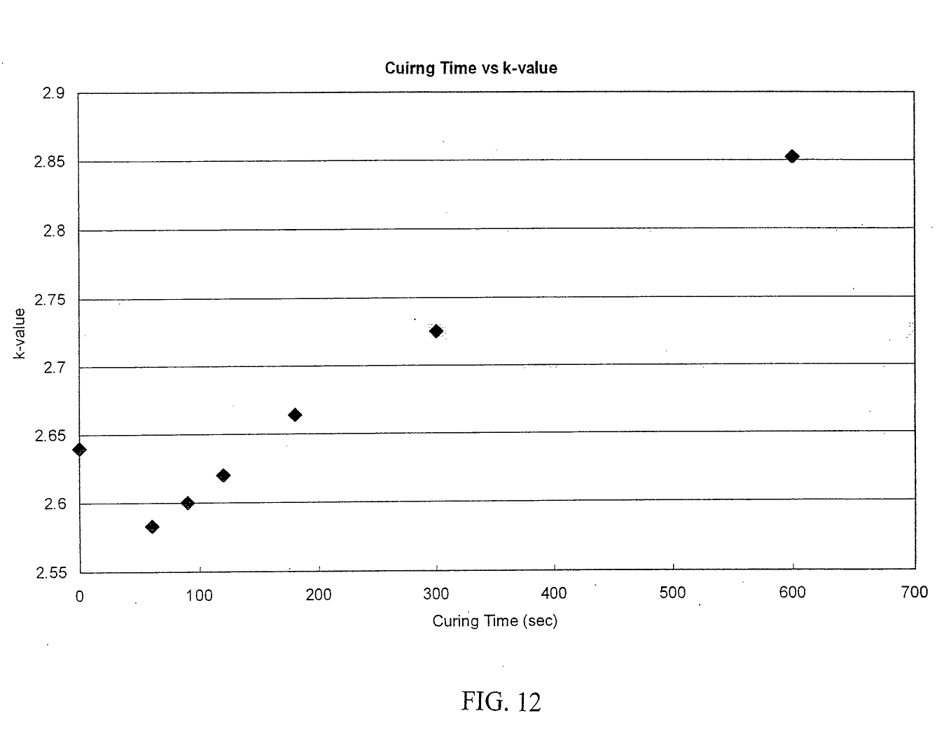

If one example of the above-mentioned change in dielectric constant values is graphed out, a graph will be one shown in FIG. 12 (See Embodiment 14). In this example, after ultraviolet light emission is started, dielectric constant values drop for about 50 sec.; after that, they are shifted to rise, and in about 150 sec., they rise to approximately the same value as the one when the ultraviolet light emission was started; and from then on, the film becomes oxidized and its dielectric constant further rises. The UV emission time with which a dielectric constant is effectively lowered is about 10% to about 50% (including 20%, 30%, 40%, and values between the foregoing) (5-80% in one embodiment) of the UV emission time with which a dielectric constant of a thin film is lowered after the ultraviolet light emission is started, and then the dielectric constant rises and goes back to a dielectric constant value when the light emission was started. The UV emission time can be set at about 5 sec. to about 300 sec. in one embodiment; preferably about 20 sec to about 200 sec.; more preferably about 30 sec to about 100 sec.

Additionally, in the above, in order to determine the UV emission time, dielectric constant values are measured at approx. three different points of time (e.g., after 50 sec., after 100 sec.) including at the time of starting the ultraviolet light emission; based on dielectric constant values obtained, the time when a dielectric constant value becomes the same level as that at the start of ultraviolet light emission is estimated; the UV emission time can be estimated based on the estimated value, i.e., about 10% to about 50% of the estimated value. Furthermore, by combining a dielectric constant value obtained as a result of the ultraviolet light emission for the estimated time and data obtained from three different points of time, more accurate UV emission time can be identified. (If necessary, by repeating the measurement and estimation several times, more accurate UV emission time can be identified.)

In another embodiment, lowering a dielectric constant of a thin film can be achieved by starting ultraviolet light emission and stopping the emission before the thin film becomes oxidized. Because whether the film is oxidized or not can be understood by, e.g., FT-IR data, UV emission time can also be identified in the same manner mentioned above.

As mentioned above, in order to provide uniform film properties improvement effects including lowered dielectric constants on the entire thin film formed on a semiconductor substrate, it is preferable to uniformize the illumination, temperature and/or gas atmosphere which comprise an environment of uniform ultraviolet light emission. In other words, in one embodiment, at least one of the following is adopted for the purpose of uniformization:

(1) By changing a shape and a thickness of a filter, the illumination of ultraviolet light is controlled.

(2) By disposing each ultraviolet light emitter and reflector appropriately, positioning of the ultraviolet light emitters and reflectors are adjusted and their angles are fine-adjusted.

(3) A heater is rotated on its central axis.

(4) A distance between ultraviolet light emitters and the heater is optimized.

(5) A heater having excellent temperature uniformity is used.

(6) By symmetrically disposing gas inlet ports in a flange for introducing gas, gas is introduced uniformly into the chamber.

By adopting at least any one of (1)-(6), uniform effects on the entire thin film are obtained.

### EXAMPLES

Embodiments of the present invention are described below. However, the present invention is not limited to these embodiments.

Common Conditions:

Common conditions in each embodiment are as described below. As a reactor, the one possessing a configuration shown in FIG. 3A, FIG. 5B, FIG. 7 and FIG. 8 was used. Additionally, in this embodiment, film characteristics of thin film materials before being exposed to ultraviolet light emission are as follows:

Film Characteristics of a Thin Film Material, DMOTMDS

Dielectric constant: 2.65

Modulus: 5.0 GPa

Hardness: 0.9 GPa

RI (n): 1.360 at 633 nm

Film Characteristics of a Thin Film Material, DMDMOS

Dielectric constant: 2.75

Modulus: 5.5 GPa

Hardness: 1.0 GPa

RI (n): 1.390 at 633 nm

### Embodiment 1: Process Conditions and Thin Film Formation Results in this Embodiment are Shown Below

Process Conditions:

Thin film material: DMOTMDS

Treatment time: 90 sec.

Intensity of illumination: 10 mW/cm²

N₂: 4,000 sccm

Pressure: 4 Torr

Heater temperature: 430 degrees

UV Treatment Results:

Dielectric constant: 2.6

Modulus: 7.9 GPa

Hardness: 1.5 GPa

RI (n): 1.364 at 633 nm

### Embodiment 2: Process Conditions and Thin Film Formation Results in this Embodiment are Shown Below

Process Conditions:

Thin film material: DMOTMDS

Treatment time: 180 sec.

Intensity of illumination: 10 mW/cm²

N₂: 4,000 sccm

Pressure: 4 Torr

Heater temperature: 430 degrees

UV Treatment Results:

Dielectric constant: 2.66

Modulus: 11.3 GPa

Hardness: 2.0 GPa

RI (n): 1.373 at 633 nm

### Embodiment 3: Process Conditions and Thin Film Formation Results in this Embodiment are Shown Below

Process Conditions:

Thin film material: DMOTMDS

Treatment time: 60 sec.

Intensity of illumination: 10 mW/cm²

N₂: 4,000 sccm

Pressure: 50 Torr

Heater temperature: 430 degrees

UV Treatment Results:

Dielectric constant: 2.59

Modulus: 7.7 GPa

Hardness: 1.4 GPa

RI (n): 1.362 at 633 nm

A FT-IR graph showing the state of CH₃ groups in the thin film before and after UV emission is shown in FIG. 15. Additionally, a FT-IR graph showing the state of Si—CH₃ groups before and after UV emission is shown in FIG. 16. It is seen that a level of CH₃ groups and a level of Si—CH₃ groups are respectively reduced by ultraviolet light emission (although they did not disappear completely).

### Embodiment 4: Process Conditions and Thin Film Formation Results in this Embodiment are Shown Below

Process Conditions:

Thin film material: DMOTMDS

Treatment time: 60 sec.

Intensity of illumination: 10 mW/cm²

N₂: 1,700 sccm

Pressure: 250 Torr

Heater temperature: 430 degrees

UV Treatment Results:

Dielectric constant: 2.60

Modulus: 7.7 GPa

Hardness: 1.4 GPa

RI (n): 1.362 at 633 nm

### Embodiment 5: Process Conditions and Thin Film Formation Results in this Embodiment are Shown Below

Process Conditions:

Thin film material: DMOTMDS

Treatment time: 60 sec.

Intensity of illumination: 10 mW/cm²

N₂: 3,650 sccm

Pressure: 500 Torr

Heater temperature: 430 degrees

UV Treatment Results:

Dielectric constant: 2.59

Modulus: 7.7 GPa

Hardness: 1.4 GPa

RI (n): 1.362 at 633 nm

### Embodiment 6: Process Conditions and Thin Film Formation Results in this Embodiment are Shown Below.

Process Conditions:

Thin film material: DMOTMDS

Treatment time: 60 sec.

Intensity of illumination: 10 mW/cm²

N₂: 8,500 sccm

Pressure: 760 Torr

Heater temperature: 430 degrees

UV Treatment Results:

Dielectric constant: 2.61

Modulus: 7.6 GPa

Hardness: 1.4 GPa

RI (n): 1.362 at 633 nm

### Embodiment 7: Process Conditions and Thin Film Formation Results in this Embodiment are Shown Below

Process Conditions:

Thin film material: DMOTMDS

Treatment time: 60 sec.

Intensity of illumination: 10 mW/cm²

Ar: 4,000 sccm

Pressure: 4 Torr

Heater temperature: 430 degrees

UV Treatment Results:

Dielectric constant: 2.61

Modulus: 7.1 GPa

Hardness: 1.3 GPa

RI (n): 1.360 at 633 nm

### Embodiment 8: Process Conditions and Thin Film Formation Results in this Embodiment are Shown Below.

Process Conditions:

Thin film material: DMOTMDS

Treatment time: 60 sec.

Intensity of illumination: 10 mW/cm²

He: 2,000 sccm

Pressure: 4 Torr

Heater temperature: 430 degrees

UV Treatment Results:

Dielectric constant: 2.61

Modulus: 6.7 GPa

Hardness: 1.2 GPa

RI (n): 1.360 at 633 nm

### Embodiment 9: Process Conditions and Thin Film Formation Results in this Embodiment are Shown Below

Process Conditions:

Thin film material: DMOTMDS

Treatment time: 60 sec.

Intensity of illumination: 10 mW/cm²

N₂: 8,000 sccm

H2: 80 sccm

Pressure: 50 Torr

Heater temperature: 430 degrees

UV Treatment Results:

Dielectric constant: 2.66

Modulus: 7.9 GPa

Hardness: 1.4 GPa

RI (n): 1.360 at 633 nm

### Embodiment 10: Process Conditions and Thin Film Formation Results in this Embodiment are Shown Below

Process Conditions:

Thin film material: DMOTMDS

Treatment time: 60 sec.

Intensity of illumination: 10 mW/cm²

N₂: 2,500 sccm

CO₂: 400 sccm

Pressure: 50 Torr

Heater temperature: 430 degrees

UV Treatment Results:

Dielectric constant: 2.69

Modulus: 9.5 GPa

Hardness: 1.6 GPa

RI (n): 1.361 at 633 nm

FIG. 11 is a FT-IR graph showing a case in which CO₂ was not added and a case in which CO₂ was added. By adding CO₂, it is seen that hydrophilic groups, Si—H groups and Si—OH groups were effectively controlled.

### Embodiment 11: Process Conditions and Thin Film Formation Results in this Embodiment are Shown Below.

Process Conditions:

Thin film material: DMOTMDS

Treatment time: 15 sec.

Intensity of illumination: 34m W/cm²

N₂: 10,000 sccm

Pressure: 760 Torr

Heater temperature: 350 degrees

UV Treatment Results:

Dielectric constant: 2.63

Modulus: 6.7 GPa

Hardness: 1.1 GPa

RI (n): 1.358 at 633 nm

### Embodiment 12: Process Conditions and Thin Film Formation Results in this Embodiment are Shown Below

Process Conditions:

Thin film material: DMOTMDS

Treatment time: 15 sec.

Intensity of illumination: 50 mW/cm²

N₂: 10,000 sccm

Pressure: 760 Torr

Heater temperature: 300 degrees

UV Treatment Results:

Dielectric constant: 2.71

Modulus: 6.6 GPa

Hardness: 1.0 GPa

RI (n): 1.358 at 633 nm

### Embodiment 13: Process Conditions and Thin Film Formation Results in this Embodiment are Shown Below

Process Conditions:

Thin film material: DMDMOS

Treatment time: 60 sec.

Intensity of illumination: 10 mW/cm²

N₂: 4,000 sccm

Pressure: 50 Torr

Heater temperature: 430 degrees

UV Treatment Results:

Dielectric constant: 2.70

Modulus: 7.0 GPa

Hardness: 1.3 GPa

RI (n): 1.390 at 633 nm

Embodiment 14: Process Conditions and Thin Film Formation Results in this Embodiment are Shown Below

Process Conditions:

Thin film material: DMOTMDS

Intensity of illumination: 10 mW/cm²

N₂: 4,000 sccm

Pressure: 4 Torr

Heater temperature: 430 degrees

In Embodiment 14, changes in dielectric constants were measured by changing UV treatment time. Measurement results are shown in FIG. 12. Among the values measured, dielectric constant values became lowest in approx. 60 sec. after ultraviolet light emission was started; after ultraviolet light emission was started, in 180 sec., dielectric constant values exceeded the value at the start of the ultraviolet light emission; and after that values continued to increase.

### Comparative Example 1

### Process Conditions and Thin Film Formation Results in this Embodiment are Shown Below

Process Conditions:

Thin film material: DMOTMDS

Treatment time: 1,860 sec.

Intensity of illumination: 10 mW/cm²

N₂: 4,000 sccm

Pressure: 50 Torr

Heater temperature: 430 degrees

As a result of ultraviolet light emission in this comparative example, CH₃ groups and Si—CH₃ groups in the thin film nearly disappeared by excessive ultraviolet light emission, and Si—O structure was increased (FIG. 13). Additionally, by the excessive ultraviolet light emission, a SiOCH film in this embodiment became oxidized, and showed FT-IR similar to that of the control TEOS oxide film (FIG. 14).

What is claimed is:

1. An apparatus for treating a substrate comprising:
a chamber an internal pressure of which can be controlled from a vacuum to the vicinity of an atmospheric pressure;
multiple ultraviolet light emitters provided inside the chamber;
a heater provided facing and parallel to the emitters inside the chamber;
a filter being disposed between the emitters and the heater and used for uniformizing the illumination of ultraviolet light; and
at least any one of the following for uniformly distributing the illumination of ultraviolet light emitted from said emitters onto a surface of said heater:
(A) a configuration wherein said emitters composed of inside emitters disposed within a plane parallel to the heater surface and outside emitters arranged on an outer side of said inside emitters and disposed closer to the heater surface than said inside emitters;
(B) a configuration which further comprises reflectors for emitting reflected light as well as direct light of said emitters onto the substrate, and an angle-adjusting mechanism for enabling to vary reflection angles of said reflectors, or
(C) a configuration which further comprises a distance-adjusting mechanism for enabling to change a distance set for ultraviolet light emission between said filter and said heater.

2. The apparatus according to claim 1, wherein multiple gas inlet ports for introducing gas into said chamber in a direction from an inner circumferential surface to a center of said chamber are disposed.

3. The apparatus according to claim 1, further comprising a rotating mechanism for rotating said heater on its axis.

4. The apparatus according to claim 1, wherein said filter has a convex shape where a thickness in the vicinity of its center is thicker than a thickness in the vicinity of its outer perimeter, and said convex shape portion is processed as a curved surface.

5. The apparatus according to claim 1, wherein said emitters comprise inside emitters disposed within a plane parallel to the heater surface and outside emitters arranged on an outer side of said inside emitters and disposed closer to the heater surface than said inside emitters.

6. The apparatus according to claim 1, wherein said chamber comprises an upper chamber for housing said ultraviolet light emitters, a lower chamber surrounding said heater, and a flange installed between said upper chamber and said lower chamber.

7. The apparatus according to claim 6, wherein said filter is supported between said flange and said upper chamber.

8. The apparatus according to claim 6, wherein in said flange, multiple gas inlet ports for introducing gas into said chamber in a direction from an inner circumferential surface to a center of said flange are disposed.

9. The apparatus according to claim 8, wherein said multiple gas inlet ports are disposed on the inner circumferential surface of said flange at even intervals.

10. The apparatus according to claim 1, further comprising a control unit installed on top of said chamber for controlling ultraviolet light emission by said ultraviolet light emitters.

11. The apparatus according to claim 1, which comprises all configurations A, B, and C.

12. An apparatus for treating a semiconductor substrate, comprising:
a chamber an internal pressure of which can be controlled from a vacuum to the vicinity of an atmospheric pressure;
multiple ultraviolet light emitters provided inside the chamber;
a heater provided facing and parallel to the emitters inside the chamber;
a filter being disposed between the emitters and the heater and used for uniformizing the illumination of ultraviolet light; and
multiple gas inlet ports for introducing gas into the chamber in a direction from an inner circumferential surface to the center of the chamber.

13. The apparatus according to claim 12, wherein said chamber comprises an upper chamber for housing said ultraviolet light emitters, a lower chamber surrounding said heater, and a flange installed between said upper chamber and said lower chamber.

14. The apparatus according to claim 13, wherein said filter is supported between said flange and said upper chamber.

15. The apparatus according to claim 13, wherein in said flange, multiple gas inlet ports for introducing gas into said chamber in a direction from an inner circumferential surface to a center of said flange are disposed.

16. The apparatus according to claim 15, wherein said multiple gas inlet ports are disposed on an inner circumferential surface of said flange at even intervals.

17. A method for treating a semiconductor substrate comprising the steps of:
forming a low-k thin film on a substrate;
lowering a dielectric constant of the thin film formed by starting ultraviolet light emission to the thin film under a given set of conditions; and
continuing ultraviolet light emission under the given set of conditions and stopping the ultraviolet light emission at or near a lowest point where a dielectric constant value of the thin film becomes lowest and thereafter begins rising.

18. The method according to claim 17, wherein the ultraviolet light has an intensity of illumination of 1-50 mW/cm².

19. The method according to claim 17, wherein ultraviolet light emission continues for less than 100 sec.

20. The method according to claim 17, further comprising a step of establishing an N₂ or inert gas atmosphere before said ultraviolet light emission.

21. The method according to claim 20, wherein CO₂ is further added.

22. The method according to claim 17, wherein said low-k thin film is a film containing methyl groups.

23. The method according to claim 17, wherein said low-k thin film is a low-k C-doped silicon oxide film or silicon carbide system film.

24. A method for treating semiconductor substrates comprising the steps of:
forming a low-k thin film on a substrate;
lowering a dielectric constant of the thin film formed by starting ultraviolet light emission to the thin film under a given set of conditions; and
continuing ultraviolet light emission under the given set of conditions and stopping the ultraviolet light emission before the thin film is oxidized to an oxide film.

25. A method for treating semiconductor substrates comprising the steps of:
forming a thin film having a first dielectric constant on a substrate;
determining emission time required for the dielectric constant value of the thin film to return to the first dielectric constant after the dielectric constant value of the thin film drops and then rises when ultraviolet light is emitted onto the thin film under a given set of conditions; and
emitting ultraviolet light to a thin film under the given set of conditions for 10-50% of the emission time.
